(19) United States
(12) Patent Application Publication
(10) Pub. No.: US 2020/0027733 A1
(43) Pub. Date: Jan. 23, 2020

(54) DIRECTIONAL DEPOSITION FOR PATTERNING THREE-DIMENSIONAL STRUCTURES

(71) Applicant: Varian Semiconductor Equipment Associates, Inc., Gloucester, MA (US)

(72) Inventor: JOHN HAUTALA, Beverly, MA (US)

(73) Assignee: Varian Semiconductor Equipment Associates, Inc., Gloucester, MA (US)

(21) Appl. No.: 16/041,456

(22) Filed: Jul. 20, 2018

(51) Int. Cl. H01L 21/02; B29C 64/245; H05K 3/02; B29C 64/159; B29C 64/371

(52) U.S. Cl. CPC H01L 21/02639; B29C 64/245; B29L 2031/3425; B29C 64/159; B29C 64/371; H05K 3/022

(57) ABSTRACT

A method for patterning a three-dimensional structure is provided. The method may include providing a substrate, the substrate including the three-dimensional structure, and directing a depositing species from a deposition source to the three-dimensional structure, wherein a layer forms on the three-dimensional structure. The method may further include directing angled ions to the three-dimensional structure from an ion source, wherein the angled ions impinge on a first region of the layer and do not impinge on a second region of the layer. As such, the first region may form a densified layer portion having a first density, and the second region may form an undensified layer portion having a second density, less than the first density.

### FIELD

The present embodiments relate to device processing, and more particularly, to selective deposition of a given material on a substrate.

### BACKGROUND

In the present day, semiconductor and other devices are scaled to smaller and smaller deposition, where such devices may be formed of many different materials, having complex structures, often arranged in multiple different layers on a substrate. In recently developed technology, three dimensional structures are employed for transistors, storage devices, and related components of semiconductor devices. Formation of such structures may require patterning of various three dimensional precursor structures, including masks. Heretofore, the formation of a given device structure or mask structure may entail blanket deposition of a material layer on a given substrate including three dimensional structures. The blanket deposition may be followed by lithographic patterning of the material layer, and performing one or more etch operations to form the final structure. Such approaches may not fully harness the ability to use three dimensional structures to aid in patterning of the device to be formed.

With respect to these and other considerations the present disclosure is provided.

### BRIEF SUMMARY

In one embodiment, a method for patterning a three-dimensional structure is provided. The method may include providing a substrate, the substrate including the three-dimensional structure, and directing a depositing species from a deposition source to the three-dimensional structure, wherein a layer forms on the three-dimensional structure. The method may further include directing angled ions to the three-dimensional structure from an ion source, wherein the angled ions impinge on a first region of the layer and do not impinge on a second region of the layer. As such, the first region may form a densified layer portion having a first density, and the second region may form an undensified layer portion having a second density, less than the first density.

In another embodiment, a method may include generating a plasma in a deposition source and providing a substrate, adjacent the deposition source, the substrate including a three-dimensional structure. The method may include directing a depositing species from the deposition source through a source aperture to the three-dimensional structure, at an angle of incidence with respect to a perpendicular to a plane of the substrate, wherein at the angle of incidence, the depositing species are shadowed by a portion of the three-dimensional structure. As such, the depositing species may impinge on a first region of the three-dimensional structure and do not impinge on a second region of the three-dimensional structure, wherein a layer forms on the three-dimensional structure, the layer having a first thickness in the first region, and comprising a second thickness in the second region, less than the first thickness.

In another embodiment, an apparatus may include a process chamber to house a substrate, the substrate comprising a three-dimensional structure, as well as an angled deposition source, disposed in a first section of the process chamber and arranged to generate a depositing species. The apparatus may further include an angled ion source, disposed in a second section of the process chamber and arranged to direct angled ions to the substrate, and a substrate stage arranged to scan the substrate along a first direction between the first section and the second section. The apparatus may also include a controller, coupled to the angled deposition source and the ion source, where the controller is arranged to send a first control signal to bias the substrate at a first negative potential with respect to the angled ion source when the substrate stage is disposed in the second section.

### BRIEF DESCRIPTION OF THE DRAWINGS

FIG. 1 shows a selective deposition arrangement, according to embodiments of the disclosure;

FIG. 2 shows a three-dimensional structure after post-deposition etching, following the scenario of FIG. 1;

FIG. 3 shows another arrangement for selective deposition, according to some embodiments of the disclosure;

FIG. 4 shows an arrangement for selective deposition, according to further embodiments of the disclosure;

FIG. 5 shows a further arrangement for selective deposition, according to additional embodiments of the disclosure;

FIG. 6 illustrates a block diagram of a processing apparatus;

FIG. 7A depicts a deposition arrangement according to additional embodiments of the disclosure;

FIG. 7B shows a three-dimensional structure after post-deposition etching, following the scenario of FIG. 7A;

FIG. 7C depicts a further deposition arrangement according to additional embodiments of the disclosure; and

FIG. 8 depicts an exemplary process flow. shows side view of a processing apparatus, according to various embodiment of the disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

In accordance with some embodiments, novel approaches for selectively forming a material on a substrate, and in particular, novel approaches are provided for building device structures using selective deposition facilitated by angled ions. In various embodiments directional deposition of a densified layer is facilitated using a plurality of sources, including a deposition source and an ion source. When a substrate is scanned between the deposition source and ion source, selective formation of a densified layer may be accomplished on select regions of a substrate. In particular, the present embodiments harness the geometry of a three dimensional structure to ensure the densified layer is formed on the select regions of the substrate while not forming on other regions of the substrate. In this manner, novel mask features may be formed during patterning of a device, or novel device structures may be formed. The present embodiments facilitate novel process integration schemes for forming integrated circuit devices by allowing formation of layers or partial layers, such as spacers, just on portions of pre-existing structures, such as formation of spacers on one sidewall of a device structure while not forming on another sidewall, or on a trench.

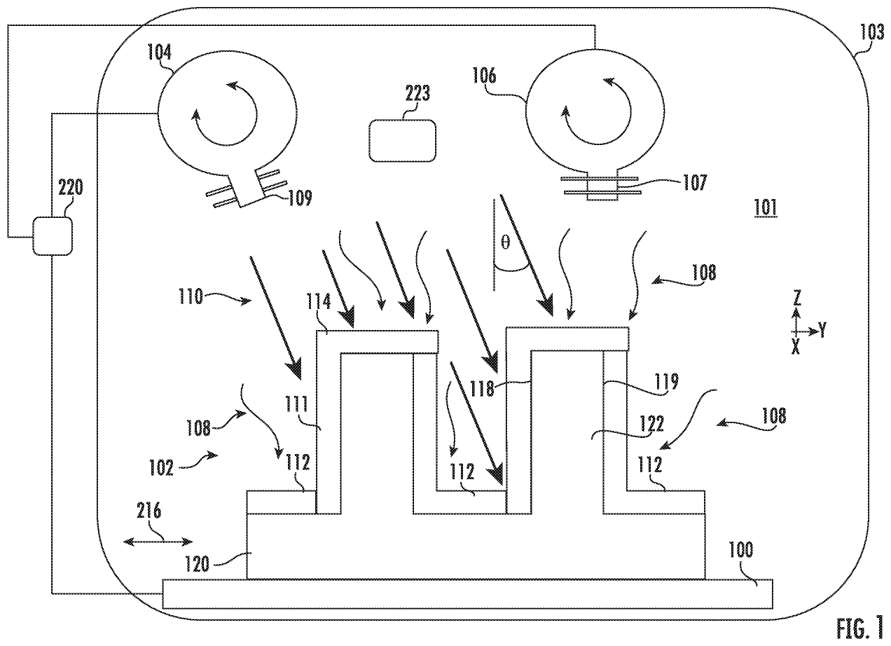

Turning now to FIG. 1, there is shown an arrangement for selective deposition, according to embodiments of the disclosure. The arrangement includes a substrate stage 100 to scan a substrate 120 along a direction 216 between a first position adjacent a deposition source 106 to a second position adjacent an ion source 104. In sum embodiments, the arrangement may use a processing apparatus 101, including a process chamber 103 to house the substrate 120. In various embodiments, the deposition source 106 may be disposed in a first region of the process chamber 103, while the ion source is disposed in a second region of the process chamber 103. The processing apparatus 101 may further include a controller 223, coupled to the deposition source 106 and to the ion source 104. The controller 223 may be arranged to control various components of the processing apparatus 101, as detailed below. In brief, the controller may be used to send control signals to a bias source 220 to bias the process chamber 103 with respect to the ion source 104, or bias the process chamber 103 with respect to the substrate 120, to change the orientation of the ion source 104 or orientation of the deposition source 106, to scan the substrate stage 100, and so forth.

As detailed in the embodiments to follow, by directing depositing species 108 and angled ions 110 to the substrate 120, a novel selective and directional deposition takes place on the substrate 120. In some embodiments, the depositing species 108 and angled ions 110 may be directed to the same region of the substrate 120, either simultaneously, or in sequential fashion. In some embodiments, scanning the substrate 120 may take place while the substrate 120 is exposed simultaneously to the depositing species 108 and angled ions 110. In other embodiments where the angled ions 110 and depositing species are directed towards different regions of the process chamber 103, the substrate stage 100 may be scanned so the substrate 120 is exposed sequentially to depositing species 108 from the deposition source 106 and to angled ions 110 from the ion source 104. As shown in FIG. 1, the substrate 120 includes a three-dimensional structure, referred to as 3-D structure 102. The 3-D structure 102 may represent a set of pillars, mesas, lines, fin structures, vias, trenches, mask features, or other structures having surfaces extending proud of a substrate plane or into a substrate. As such, the 3-D structure 102 may present certain features or portions of features tending to shadow other features from incident species depending upon the angle of incidence of the incident species.

In the embodiment of FIG. 1, the arrangement may represent processing in a deposition apparatus, where depositing species are directed from the deposition source 106 to the 3-D structure 102, to form a layer over select portions of the 3-D structure 102. Notably, the 3-D structure 102 may be microscopic in dimension where the width, length (in the X or Y direction of the Cartesian coordinate system shown) or height (along the Z-direction) of the features of the 3-D structure are on the order of micrometers, hundreds of nanometers, tens or nanometers, or nanometers in different non-limiting embodiments. As such, a substrate, such as a wafer containing integrated circuit devices, may include many hundreds, thousands, millions, or billions of structures as represented by the 3-D structure 102. Said differently, the 3-D structure 102 may represent thousands, millions, or billions of individual structures, such as 3-D lines, where the size of the 3-D lines may be on the order of micrometers or nanometers.

The deposition source 106 may provide depositing species 108, in the form of ions, excited neutrals, radicals, or other species capable of depositing on the substrate 120. In some examples, a feed gas may be fed into the deposition source 106, providing the appropriate species such as SiH₄, CH₄, or NH₃, optionally in combination with other gases, such as oxygen, nitrogen, hydrogen, and so forth, for depositing a given layer, such as silicon, carbon, silicon nitride, silicon oxide, and so forth. In some embodiments, the deposition source 106 may be a first plasma chamber, excited by a microwave or RF power source to generate a plasma including reactive species. The depositing species 108 may be provided as known reactive species to the substrate 120, where the depositing species 108 are directed through the orifice 107 toward the substrate 120, and may generally diffuse toward the substrate 120 and impinge upon the substrate 120 at many different angles. In some examples, the depositing species 108 may impinge upon the substrate 120 in an isotropic fashion and may tend to form a conformal coating, as represented by the layer 111. In some embodiments, the depositing species 108 may deposit in a manner where the deposition is symmetrically arranged on different surfaces of the 3-D structure 102, while not being isotropic. For example, where the orifice 107 faces downwardly as shown in FIG. 1, the depositing species may deposit on all exposed surfaces while depositing on horizontal surfaces to a greater extent than on vertical surfaces, and may deposit equally on a first sidewall 118 and as second sidewall 119.

Examples of suitable materials for layer 111 include materials amendable for deposition by known plasma enhanced chemical vapor deposition techniques, including Si, SiO₂, SiN, SiC, SiCN, SiOC, SiOCN, Ge, SiGeₓ, TiN, among others. In some examples, during deposition of layer 111, the substrate stage 100 (or a platen disposed thereon) may be held at room temperature, or heated up to 500° C. The embodiments are not limited in this context.

The layer 111 may be formed under conditions where the depositing species 108 condense upon the substrate with low kinetic energy, such as less than a few eV, and in some cases less than 1 eV energy. In some embodiments, the substrate stage 100 may be biased with respect to the deposition source 106 at zero volts or a slight positive voltage (positive potential), such as +10 V to +50 V. Under these conditions, any positive ions tending to stream out of the deposition source 106 will be repelled from the substrate 120 and tend not to impact the substrate 120. As such, the layer 111 may tend to form as a low-density layer, having poor quality due to the tendency of the depositing species to form open, porous structures, absent energetic bombardment. By way of background, layers such as silicon, silicon nitride, silicon oxide, carbon, and other layers, when deposited by chemical vapor deposition, or by plasma assisted chemical vapor deposition, may tend to form low density, porous structures when substantial energetic bombardment is not provided. Such energetic bombardment may entail ion bombardment where ion energy exceeds 0 eV, 100 eV, or greater, depending upon the exact chemistry of the depositing species, substrate temperature, and other parameters.

In some embodiments, the deposition source 106 may be rotatable around (about) an axis, such as the X-axis in the Cartesian coordinate system shown. In this manner the trajectories of depositing species 108 may at least partially align along a direction defined by the orientation of the orifice 107. In the example of FIG. 1, the orifice 107 may be oriented in a manner where the trajectories of depositing species are distributed symmetrically about a perpendicular to a plane of the substrate (X-Y plane), where the perpendicular is represented by the Z-axis. In other embodiments discussed below, the orifice 107 may be disposed in different orientations to provide angled depositing species.

In the embodiment of FIG. 1, the ion source 104 may be a second plasma chamber generating a plasma containing inert gas ions such as Ar⁺, Kr⁺, Xe⁺, or reactive ions, such as O+, N+, O2+. N2+, and so forth. According to various embodiments, the ion source 104 and the deposition source 106 may be arranged with a known triode extraction system, including ground and suppression electrodes, as suggested in FIG. 1. The embodiments are not limited in this context. The ion source 104 may act as an angled ion source where ions are extracted from the ion source 104 through orifice 109 and directed as angled ions 110 to the substrate 120. Notably, the angled ions 110 may be shadowed by features in the 3-D structure 102. For example, the angled ions 110 may be provided as a collimated ion beam, where the angled ions 110 are parallel to one another or have trajectories forming a low angular spread, such as less than 10 degrees. As such, the angled ions 110 may tend to be shadowed in like regions of similar features within the 3-D structure 102. In this manner, the angled ions 110 may impinge upon a first region 114 of the layer 111, while not impinging upon a second region 112 of the layer 111. In various embodiments, the angled ions 110 may be provided with ion energy of 50 eV up to 3 keV, or 5 keV, or 10 keV. The embodiments are not limited in this context. As such, the first region 114 may form a densified layer having a first density higher than a second density of the second region 112. According to various embodiments, the angle of incidence (θ) of angled ions 110 with respect to a perpendicular to a plane of the substrate (e.g., the X-Y plane of the Cartesian coordinate system shown) may be set by tilting the substrate with respect to an ion source or ion beam, or by tilting the ion source with respect to a substrate. In various embodiments, the angle of incidence of angled ions 110 may vary from zero degrees to 85 degrees. In addition to the angle of incidence of the angled ions 110, factors determining the position and extent of the shadowed regions, the second region 112, include the height (along the Z-axis) and spacing (in this example, along the Y-axis) between adjacent features of the 3-D structure 102.

According to various embodiments, the ion energy and the ion dose of the angled ions 110 may be adjusted according to the deposition rate of depositing species 108, forming the layer 111. At too high an ion energy or ion dose, unacceptable levels of sputtering of the layer 111 may occur, while at too low an ion energy or ion dose, the first region 114 may not achieve an acceptable density. In some embodiments, where reactive ions such as nitrogen or oxygen are directed as angled ions 110, the angled ions 110 may be used to adjust the stoichiometry (composition) of the layer 111 in the first region 114. For example, the layer 111 may be an oxide material, initially deficient in oxygen with respect to an ideal stoichiometry. Accordingly, the angled ions 110 may be provided as oxygen ions to increase the relative oxygen content of the layer 111 in one embodiment. This independent control of stoichiometry using the ion source 104 may allow formation of layer properties not easily attained by single source plasma enhanced chemical vapor deposition reactors.

In some embodiments, the formation of the layer 111 may take place in stages where the 3-D structure 102 is first exposed to depositing species 108 to deposit the layer 111 as a uniform layer, where the entirety of the layer 111 is a low-density layer. At a second stage, the substrate 120 may be moved so the 3-D structure is subsequently exposed to the ion source 104 to generate the first region 114 and the second region 112, as shown in FIG. 1. Thus, the substrate 120 may be scanned between different positions within the process chamber 103 to be sequentially exposed to the deposition source 106 and the ion source 104.

In other embodiments, the deposition source 106 and the ion source 104 may be arranged in a fashion where the 3-D structure 102 is simultaneously exposed to depositing species 108 and angled ions 110 in a manner to instantaneously generate the first region 114 and the second region 112. Notably, in variants of these embodiments of simultaneous exposure to the angled ions 110 and depositing species 108, a substrate 120, containing the 3-D structure 102 may be scanned so as to expose different portions of the substrate 120 to the depositing species 108 and angled ions 110. In other words, the angled ions 110 and depositing species 108 may be directed as relatively narrow beams of species having lateral dimensions on the order of millimeters or a few centimeters. These beams of angled ions and depositing species may overlap in a narrow process region, while the substrate 120, embodied, for example, as a 30-cm diameter wafer, is scanned through the process region to sequentially expose different portions of the substrate 120 to the simultaneous processing by the angled ions 110 and depositing species 108.

In some embodiments, the substrate 120 may be scanned back and forth so as to incrementally deposit a first sub-layer of the layer 111. Then, the first sub-layer of the layer 111 may be exposed to angled ions 110 to form a first thickness of the first region 114 and first thickness of the second region 112. Then a second sub-layer of the layer 111 may be deposited, subsequently the second sub-layer of the layer 111 may be exposed to angled ions 110 to form a second thickness of the first region 114 and second thickness of the second region 112; and so forth. This iterative process of selectively forming the first region 114 and the second region 112 may provide flexibility in choice of parameters such as ion energy of the angled ions 110. For example, to form a 20-nm thick film of the layer 111, the layer 111 may be formed in 5 sub-layers having a thickness of 4 nm. In order to densify a 4 nm-thick layer to form the first region 114, the ion energy used may be far less than the ion energy used to densify a 20 nm-thick layer in one operation.

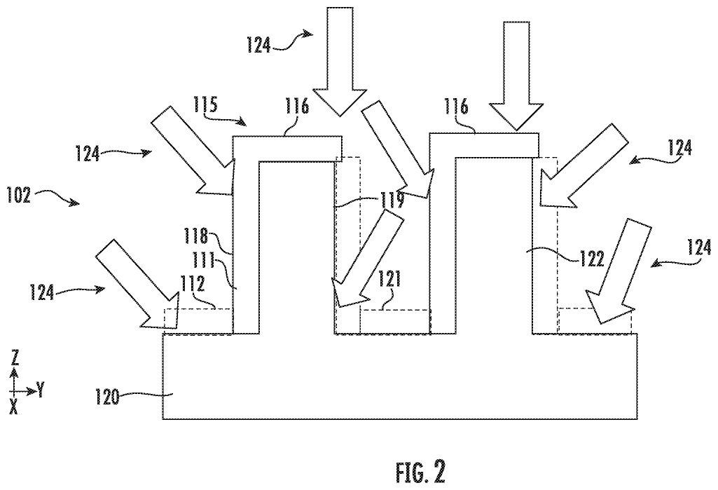

FIG. 2 shows the 3-D structure 102 after post-deposition etching, following the scenario of FIG. 1. As shown, the substrate 120 may be exposed to etchant 124, where the etchant 124 is selected to etch material of the layer 111. The etchant 124 may be a liquid etchant or a plasma etchant, or other chemical vapor etchant in different embodiments. The etchant 124 may be an isotropic etchant, tending to etch at a similar or same rate in different directions. By virtue of the first region 114 having a higher density, the etchant 124 may act as a selective etch, wherein the undensified layer portion is removed in the second region 112 of the layer 111, while at least a part of the densified layer portion remains in the first region 114 of the layer 111. Depending upon the exact material for layer 111, the etchant 124, and the degree of densification provided by the angled ions 110, the second region 112 may be etched with respect to the first region 114 at an etch rate ratio of 2/1, 5/1, or 10/1 in some instances. The embodiments are not limited in this context. Thus, in the example of FIG. 2, a cap structure 115 derived from the depositing species 108 remains on a top surface 116 and a first sidewall 118 of the structures 122, while material from the layer 111 is removed from a second sidewall 119, opposite the first sidewall 118, and is removed from the trench regions 121, between adjacent ones of the structures 122.

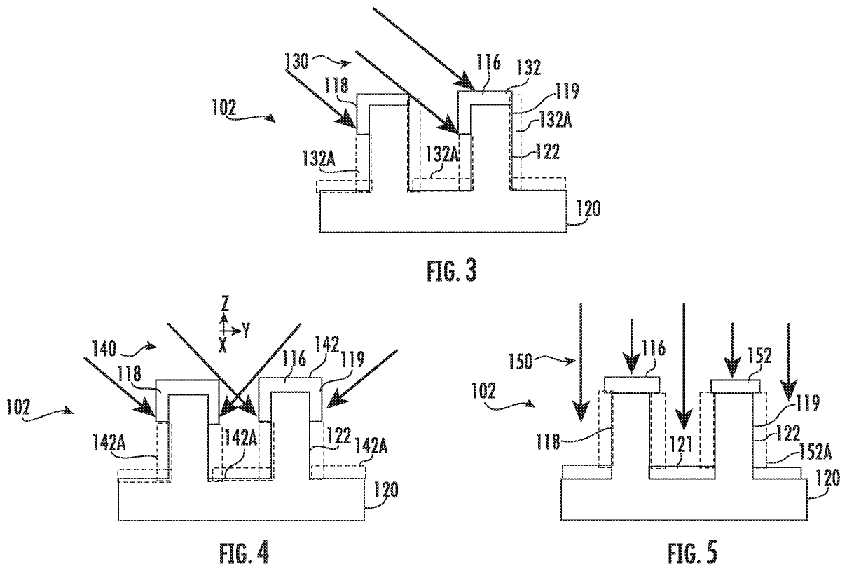

In accordance with other embodiments, the angles of incidence of the angled ions may be adjusted to selectively deposit different type of features on a 3-D structure. Turning to FIG. 3, there is shown one variant of the 3-D structure 102, after processing using angled ions 130. In this example, the structure is shown after processing where deposition of a layer may take place generally as described above with respect to FIG. 1. The instance of processing of the 3-D structure 102 in FIG. 3 represents the result of post-deposition etching, as generally described with respect to FIG. 2. In this example, low density regions, shown as second regions 132A, were not exposed to the angled ions 130, and have been selectively etch-removed, while first regions 132, exposed to the angled ions 130 and densified, remain. The first regions 132 form a cap structure on top surfaces 116 and on an upper portion of a first sidewall 118, while not forming on portions of the second sidewall 119. Notably, the angled ions 130 form a more grazing incidence (the angle of incidence with respect to the normal to the substrate plane is larger) than for the angled ions 110. In this manner, in addition to the second sidewalls 119, the lower portions of the first sidewalls 118 are also shadowed from the angled ions 110 due to the higher angle of incidence, so the cap structure forms as shown.

Turning to FIG. 4, there is shown one variant of the 3-D structure 102, after processing using angled ions 140. In this example, the structure is shown after processing where deposition of a layer may take place generally as described above with respect to FIG. 1. The instance of processing of the 3-D structure 102 in FIG. 4 represents the result of post-deposition etching, as generally described with respect to FIG. 2. In this example, low density regions, shown as second regions 142A, were not exposed to the angled ions 140, and have been selectively etch-removed, while first regions 142, exposed to the angled ions 140 and densified, remain. The angled ions 140 may have a similar geometry to angled ions 130, except the angled ions 140 include ions directed along two different trajectories, forming a mirror image about the X-Z plane. Accordingly, the first regions 142 form a symmetrical cap structure on top surfaces 116 and on an upper portion of a first sidewall 118 and second sidewall 119, as shown.

Turning to FIG. 5, there is shown a variant of the 3-D structure 102, after processing using angled ions 150. In this example, the structure is shown after processing where deposition of a layer may take place generally as described above with respect to FIG. 1. The instance of processing of the 3-D structure 102 in FIG. 5 represents the result of post-deposition etching, as generally described with respect to FIG. 2. In this example, low density regions, shown as second regions 152A, were not exposed to the angled ions 150, and have been selectively etch-removed, while first regions 152, exposed to the angled ions 150 and densified, remain. The first regions 152 form a cap structure on top surfaces 116 as well as trench regions 121, while not forming on the first sidewall 118 or the second sidewall 119. Notably, the “angled ions” 150 form a zero-degree angle with respect to the normal (Z-axis), so first sidewalls 118 and second sidewalls 119 are not exposed to angled ions 150. Accordingly portions of the layer 111 deposited along the first sidewalls 118 and the second sidewalls 119 remain as low-density regions (second regions 152A), and are selectively etched with respect to the first regions 152.

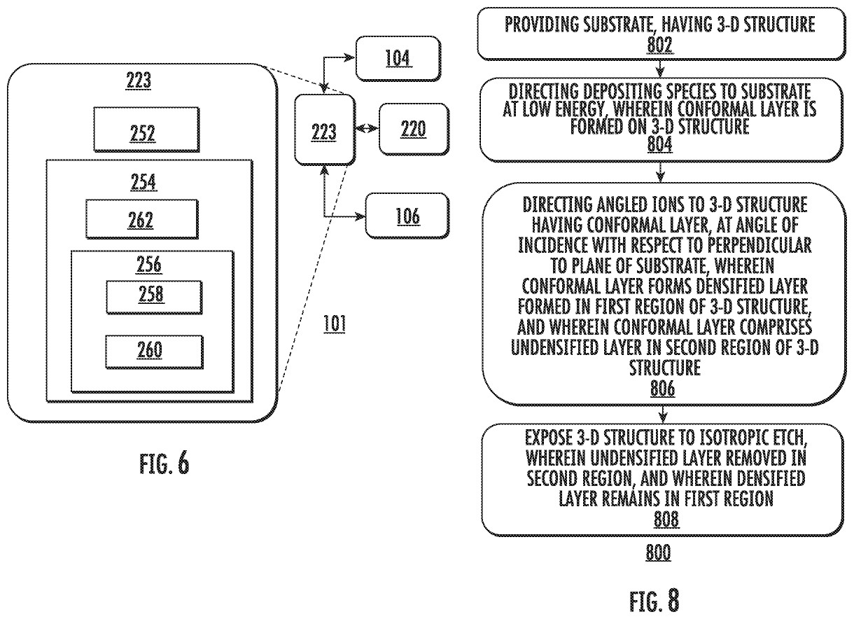

In accordance with various embodiment the processing apparatus 101 or processing apparatus 105 may further include a controller 223, where the operation of controller 223 is detailed below with respect to FIG. 6. The controller 223 may be coupled to the bias source 220, ion source 104, and deposition source 106. The controller 223 may include various components to control angled ion beam processing of a substrate.

Turning now to FIG. 6, a block diagram of processing apparatus 101 is shown, including controller 223, ion source 104, and deposition source 106. The controller 223 may be coupled to these components, for example, to send control signals and to receive signals from the components. The controller 223 may include a processor 252, such as a known type of microprocessor, dedicated semiconductor processor chip, general purpose semiconductor processor chip, or similar device. The controller 223 may further include a memory or memory unit 254, coupled to the processor 252, where the memory unit 254 contains an ion beam control routine 256. The ion beam control routine 256 may be operative on the processor 252 to monitor and adjust the angled ion beam 110, as described below.

The memory unit 254 may comprise an article of manufacture. In one embodiment, the memory unit 254 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

As further shown in FIG. 6, the ion beam control routine 256 may include an angle control processor 258, as well as deposition control processor 260. According to some embodiments, the angle control processor 258 may receive 3-D structure information a for a substrate to be processed during an ion exposure. Examples of the structure information include the height of a feature of a 3-D structure, pitch between adjacent features, the targeted region of a 3-D structure to be densified, and so forth. The angle control processor 258 may be arranged to calculate an angle of incidence for the ion beam generated by the processing apparatus 101, based upon the 3-D structure information. The angle control processor 258 may send an adjustment signal to adjust settings on the processing apparatus 101, where the adjusting of the settings (parameters) has the effect of changing the angle of incidence of the angled ion beam 110, for example. Exemplary parameters affecting angle of incidence include plasma power, bias voltage between plasma chamber and substrate, as well as separation between extraction plate and substrate (along the Z-axis). In a particular example, by varying the separation of extraction plate and substrate between approximately 5 mm and 40 mm, the angle of incidence with respect to perpendicular to a substrate plane of angled ion beam 110 may be varied from between nearly zero to up to 40 degrees. Accordingly, when the angle control processor determines based on 3-D structure information the angle of incidence is to be changed, a control signal may be sent to change plasma power, change separation between extraction plate and substrate, or change bias voltage, or a combination of the above.

The deposition control processor 260 may be arranged to send a control signal to adjust angle of the deposition source, bias applied to the deposition source, or a combination of the two, based upon receipt of deposition information. For example, the deposition information may include data on the 3-D device structures to receive a deposit, or deposition rate of a layer being deposited by the deposition source, and the angle of the deposition source.

As also shown in FIG. 6, the memory unit 254 may include a database 262, where the database may include structure information or deposition information, among other data.

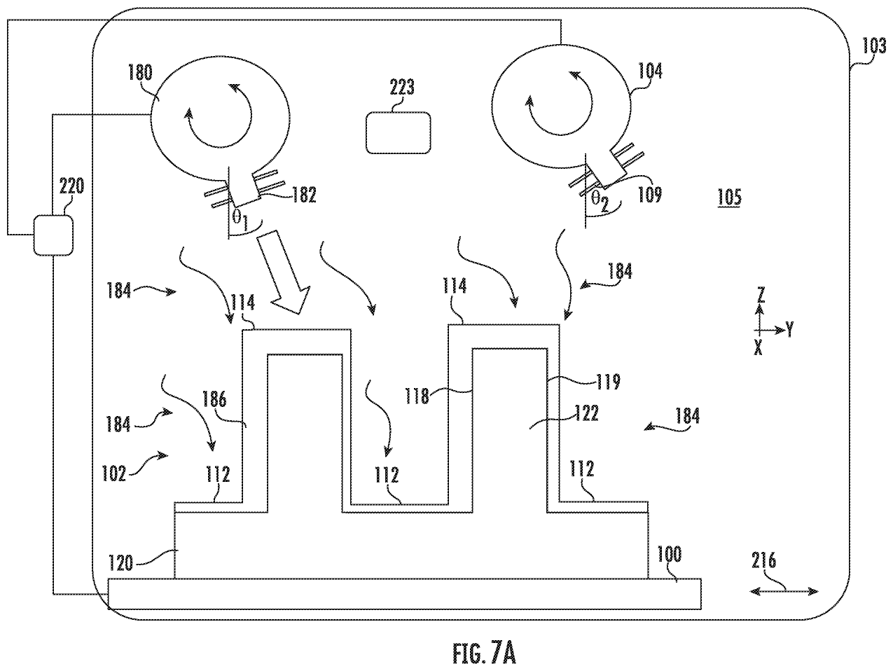

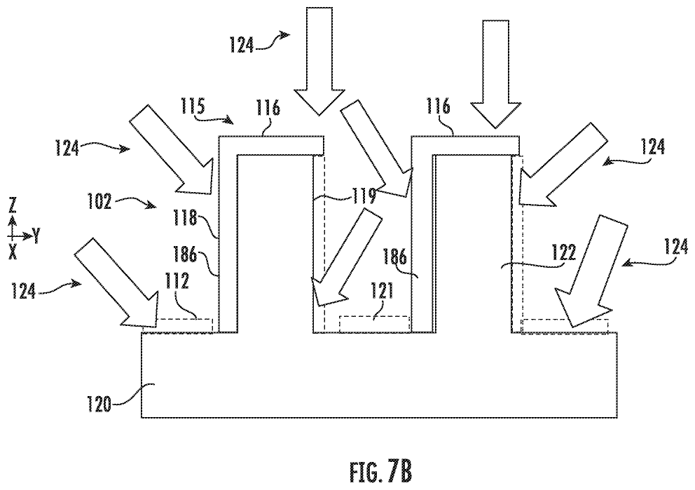

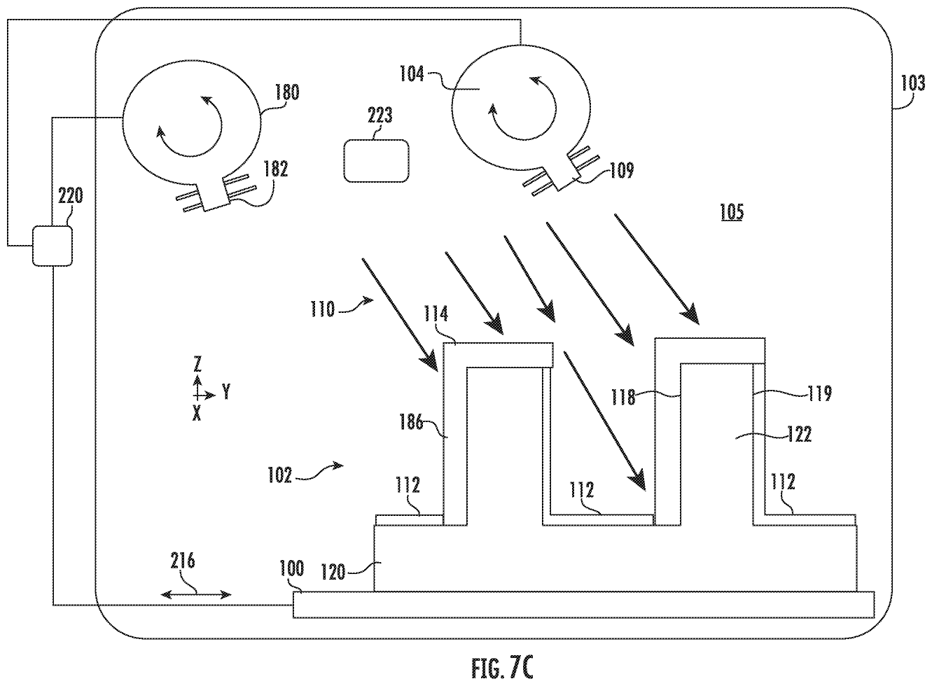

FIG. 7A depicts a deposition arrangement according to additional embodiments of the disclosure. The deposition arrangement may involve a processing apparatus 105, having similar components as processing apparatus 101, except where otherwise noted. FIG. 7B shows a three-dimensional structure after post-deposition etching, following the scenario of FIG. 9A. In the arrangement of FIG. 7A, an angled deposition source 180 is provided, where the angled deposition source 180 may be a plasma source. A plasma may be generated in the angled deposition source 180 to generate depositing species. The angled deposition source 180 may include a source aperture 182, where depositing species 184 exit the angled deposition source 180. The angled deposition source 180 may be configured similarly to the deposition source 106, where the angled deposition source 180 is rotatable about the X-axis. Again, the angled deposition source 180 may be arranged with extraction optics, as shown. The angled deposition source 180 may generate the depositing species 184 in a directional manner, where in some embodiments the depositing species 184 are collimated or partially collimated, defining trajectories not isotropic, and are aligned parallel to one another, or within an angular range, such as within 20 degrees of one another. The depositing species 184 may be generated from the angled deposition source 180. In various embodiments, the depositing species 184 may include excited species, including radicals or other neutrals.

With respect to the geometry of FIG. 7A, the depositing species 184 may form angled depositing species, having trajectories forming a non-zero angle of incidence with respect to a perpendicular to a plane of the substrate. For example, with respect to the X-Y plane of FIG. 7A, the depositing species 184 may form a non-zero angle of incidence with respect to the Z-axis. In some embodiments, a portion of species exiting the angled deposition source 180 may exit as depositing species 108, having random, or partially-collimated trajectories, as suggested in FIG. 7A. The average direction or angle of incidence of the depositing species 184 in this illustration is shown by the shaded arrow, while individual trajectories are indicated by the wavy arrows. Thus, while individual trajectories of depositing species 184 may vary, the average of all the trajectories may tend to define an average angle of incidence, θ₁, as shown. When the 3-D structure 102 is oriented as shown, the depositing species 184 may be shadowed by a portion of the 3-D structure 102. Accordingly, the depositing species 184 may impinge on the first region 114 of a three-dimensional structure and not impinge on a second region 112 of the three-dimensional structure. In this manner, a layer 186 may form on the three-dimensional structure, where the layer 186 has a first thickness in the first region 114, and a second thickness in the second region 112, less than the first thickness, as depicted schematically in FIG. 9A. In accordance with various embodiments, depositing species 184 may be generated as angled species by controlling a size of the source aperture 182 and orientation of the source aperture 182. While depositing species 184 may include various radicals and neutrals, as well as ions, the present inventors have discovered the depositing species 184 may be deposited in a selective manner as angled species as shown in FIG. 7A, in the absence of any applied bias between the substrate 120 and angled deposition source 180. This feature indicates angled flux may be directed from a deposition source to a structured substrate in the absence of energetic ions.

According to further embodiments, a portion of the depositing species 184 may be generated as ions. In various additional embodiments, a bias potential (voltage) may be applied by the bias source 220 between the angled deposition source 180 and substrate stage 100 while the depositing species 184 are directed to the substrate stage 100 as angled species. For example, a negative potential (bias) of 100 V, 200 V, 500 V may be applied to attract positive ions in the event positive ions form as part of the depositing species 184. As such, energetic bombardment by ions forming a portion of depositing species 184 may take place while depositing species 184 form the layer 186, in particular, in the first region 114. Since the ions of depositing species 184 may exhibit directionality in their trajectories along a same non-zero angle of incidence with respect to a perpendicular, the ions may also be shadowed from impinging on the second region 112. The bias between the substrate stage 100 and angled deposition source 180 may be maintained at a voltage value where the amount of sputtering of the layer 186 is maintained at or below an acceptable level. The major effect of ions in the depositing species 184 may accordingly be to densify the layer 186 through momentum transfer, as well as to adjust the composition of the layer 186 in the case where the ions may include reactive ions. As a consequence, the layer 186 may exhibit a greater thickness in the first region 114 as well as a greater density and/or a different composition as opposed to the layer 186 in the second region 112. In accordance with some embodiments, the ion source 104 need not be used to generated the layer 186, as shown.

Turning to FIG. 7B, there is shown an instance after the structure of FIG. 7A is subjected to an etch, such as a wet etch, to remove material in a selective manner. As an example, where the thickness of the layer 186 is greater in first region 114 as compared to the thickness in second region 112, a timed etch may be employed to remove a certain amount in both regions. In one instance, the layer 186 may be completely removed in the second region 112, while being thinned in the first region 114, as suggested in FIG. 7B. Additionally, in embodiments, where a bias is supplied between the angled deposition source 180 and substrate 120, energetic bombardment by ions of the depositing species 184 may impart into the layer 186 a lower etch rate in first region 114, as compared to an etch rate in the second region 112, where the layer 186 may be more porous because of not receiving ion bombardment. Thus, with a lower thickness to begin with and a faster etch rate, the layer 186 in second region 112 may be readily removed with little reduction in layer thickness in the first region 114.

FIG. 7C depicts a further deposition arrangement according to additional embodiments of the disclosure. In this embodiment, the arrangement shown in FIG. 7A may initially be performed to generate depositing species 184, discussed above. In a subsequent operation, depicted in FIG. 7C, or concurrently with the generation of depositing species 184, the ion source 104 may be activated to generate angled ions 110, as generally discussed above. Said differently, while FIG. 7C shows a separate operation to the operation in FIG. 7A, in various implementations the ion source 104 and angled deposition source 180 may be positioned and angled in a manner where depositing species 184 and angled ions 110 are provided simultaneously to the same portion of a substrate 120. Thus, in some embodiments, the substrate 120 need not be scanned to expose the same portions of the substrate to depositing species 184 and angled ions 110 in a simultaneous fashion. Notably, because the angled ions 110 and depositing species 184 may be provided as narrow beams, the substrate 120, such as a 300-mm wafer may be scanned to exposed different portions of a wafer to treatment, where a given portion of the wafer is simultaneously exposed to the angled ions 110 and depositing species.

In this manner, the angled ions 110 may densify or otherwise improve layer properties of the layer 186 in the first region 114, while not densifying the layer 186 in the second region 112. In various embodiments, the angled ions 110 may be supplied as an alternative or in addition to biasing the substrate stage 100 during exposure to the depositing species 184. Subsequently, the structure of FIG. 7C may be subjected to an etch as described above, to selectively remove the layer 186 from the second region 112.

Notably, in embodiments, where the ion source 104 and angled deposition source 180 generate angled species, the rotational angle of the angled deposition source 180, and thus the angle of incidence of the depositing species 184, may be set at a different value than the angle of incidence of the angled ions 110. This difference is indicated by θ₂, the angle of incidence of the angled ions 110. Moreover, while the aforementioned embodiments have illustrated approaches where an ion source or deposition source may be rotated with respect to a substrate, in other embodiments, the substrate stage 100 may be rotated with respect to a fixed ion source or fixed deposition source to generate a targeted angled of incidence for depositing species or for angled ions.

FIG. 8 depicts an exemplary process flow 800, according to embodiments of the disclosure. At block 802, a substrate is provided having a 3-D structure. The 3-D structure may include a set of pillars, mesas, lines, fin structures, vias, trenches, mask features, a combination of the above, or other structures having surfaces extending proud of a substrate plane or below a substrate plane. In some embodiments, the 3-D structures may have at least one dimension on the order of micrometers in size, hundreds of nanometers in size, tens of nanometers in size, or nanometers in size.

At block 804, depositing species are directed to the substrate at a low energy. As a result, a conformal layer may be formed on the 3-D structure. The depositing species may be any combination of ions, radicals, energetic neutrals, excited species, including molecules or atoms, combinations of different chemical species. The depositing species may be provided from a deposition source, such as a plasma source, where the depositing species diffuse from the plasma source and isotropically impinge upon the 3-D structure. In various embodiments, the low energy of the depositing species may refer to a low energy of the depositing species may denote a kinetic energy of less than 10 eV, or less than 1 eV. As such, little momentum is transferred from the depositing species into the conformal layer as the conformal layer is being formed, resulting in an undensified layer for the conformal layer. According to some embodiments, the substrate may be a macroscopically large substrate, such as many centimeters in width or length, and the substrate may be scanned with respect to an aperture providing a stream or beam of depositing species. In this manner, different 3-D structures, having microscopic or nanoscopic dimensions, while separated from one another by macroscopic distances, may be sequentially exposed to the depositing species as the substrate is scanned through the stream of depositing species.

At block 806, angled ions are directed to the 3-D structure, having the conformal layer, at an angle of incidence with respect to a perpendicular to the plane of the substrate. While in select embodiments, this angle of incidence may be zero, in various embodiments, the angle of incidence may range between 5 degrees and 85 degrees. As such, the conformal layer may form a densified layer in a first region of the 3-D structure, while the conformal layer remains as an undensified layer in a second region of the 3-D structure.

At block 808, the 3-D structure is exposed to an isotropic etch, wherein the undensified layer in the second region is removed from the 3-D structure, while the densified layer remains in the first region on the 3-D structure.

In sum, the present embodiments provide the advantage of the ability to perform selective deposition of a material on a 3-D structure without the use of a mask. The present embodiments also provide the additional advantage of enabling new process integration schemes for forming devices and circuitry, such as integrated circuit devices, where features such as spacers may be added selectively added to a first sidewall of a structure such as a line, pillar, trench, or via, while not being added to a second sidewall.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method for patterning a three-dimensional structure, comprising:
providing a substrate, the substrate including the three-dimensional structure;
directing a depositing species from a deposition source to the three-dimensional structure, wherein a layer forms on the three-dimensional structure; and
directing angled ions to the three-dimensional structure from an ion source, wherein the angled ions impinge on a first region of the layer and do not impinge on a second region of the layer, wherein the first region forms a densified layer portion having a first density, and wherein the second region forms an undensified layer portion having a second density, less than the first density.

2. The method of claim 1, further exposing the substrate to a selective etch, wherein the undensified layer portion is removed in the second region, and wherein at least a part of the densified layer portion remains in the first region.

3. The method of claim 1, wherein the angled ions comprise an angle of incidence with respect to a perpendicular to a plane of the substrate, wherein at the angle of incidence, the angled ions are shadowed by a portion of the three-dimensional structure.

4. The method of claim 1, wherein the angled ions comprise inert gas ions, and wherein the depositing species comprise reactive species.

5. The method of claim 1, wherein the three-dimensional structure comprises a plurality of structures, the plurality of structures including a first sidewall, a second sidewall, opposite the first sidewall, and a top surface, wherein the first region comprises the top surface.

6. The method of claim 5, wherein the first region further comprises an upper portion of the first sidewall, and not an upper portion of the second sidewall.

7. The method of claim 5, wherein the first region further comprises a first upper portion of the first sidewall and a second upper portion of the second sidewall.

8. The method of claim 5, wherein the first region further comprises a trench region, disposed between a first structure and a second structure of the plurality of structures.

9. The method of claim 1, wherein the substrate is disposed at a first position during the directing the depositing species, the method further comprising scanning the substrate to a second position, wherein the directing the angled ions takes place when the substrate is disposed at the second position.

10. The method of claim 1, wherein the substrate is disposed in a process chamber during the directing the depositing species, wherein the deposition source comprises a first plasma chamber, and wherein the substrate is biased at 0V or at a positive potential with respect to the first plasma chamber during the directing the depositing species.

11. The method of claim 1, wherein the angled ions comprise reactive ions, wherein the angled ions further adjust a composition of the first region of the layer.

12. A method, comprising:
generating a plasma in a deposition source;
providing a substrate, adjacent the deposition source, the substrate including a three-dimensional structure; and
directing a depositing species from the deposition source through a source aperture to the three-dimensional structure, at an angle of incidence with respect to a perpendicular to a plane of the substrate, wherein at the angle of incidence, the depositing species are shadowed by a portion of the three-dimensional structure,
wherein the depositing species impinge on a first region of the three-dimensional structure and do not impinge on a second region of the three-dimensional structure, wherein a layer forms on the three-dimensional structure, the layer having a first thickness in the first region, and comprising a second thickness in the second region, less than the first thickness.

13. The method of claim 12, further comprising, biasing the substrate at a negative potential with respect to the deposition source during the directing the depositing species.

14. The method of claim 12, further comprising directing angled ions from an angled ion source at the substrate, during the directing the depositing species, or after the directing the depositing species, wherein the layer forms a densified layer portion having a first density in the first region, and wherein layer forms an undensified layer portion in the second region having a second density, less than the first density.

15. The method of claim 12, further comprising exposing the substrate to an etch, wherein the layer is removed in the second region, and wherein at least a part of the layer remains in the first region.

16. An apparatus, comprising:
a process chamber to house a substrate, the substrate comprising a three-dimensional structure;
an angled deposition source, disposed in a first section of the process chamber and arranged to generate a depositing species;
an angled ion source, disposed in a second section of the process chamber and arranged to direct angled ions to the substrate;
a substrate stage arranged to scan the substrate along a first direction between the first section and the second section; and
a controller, coupled to the angled deposition source and the ion source, the controller arranged to send a first control signal to bias the substrate at a first negative potential with respect to the angled ion source when the substrate stage is disposed in the second section.

17. The apparatus of claim 16, the controller arranged to second a second control signal to bias the substrate at a second negative potential with respect to the angled ion source when the substrate stage is disposed in the first section.

18. The apparatus of claim 16, wherein the angled deposition source comprises a first plasma source, and wherein the angled ion source comprises a second plasma source.

19. The apparatus of claim 16, wherein the angled deposition source is configured to direct the depositing species at a first non-zero angle of incidence with respect to a perpendicular to a plane of the substrate, and wherein the angled ion source is configured to direct the angled ions at a second non-zero angle of incidence with respect to the perpendicular to the plane of the substrate.

20. The apparatus of claim 16, wherein the depositing species comprise at least one of: radicals, neutrals, and ions, and wherein the angled ions comprise at least one of: an inert gas, oxygen, and nitrogen.
